(19) United States
(12) Patent Application Publication
(10) Pub. No.: US 2013/0026897 A1
(43) Pub. Date: Jan. 31, 2013

(54) TRAY FOR AUDIO, COMPUTER, AND VIDEO COMPONENTS

(71) Applicants: Mike Gerutto, Long Beach, CA (US); Elliott Richard Davis, Placentia, CA (US)

(72) Inventors: Mike Gerutto, Long Beach, CA (US); Elliott Richard Davis, Placentia, CA (US)

(21) Appl. No.: 13/194,851

(22) Filed: Jul. 29, 2011

(51) Int. Cl. H05K 5/02; H05K 7/00

(52) U.S. Cl. 312/309; 312/326

(57) ABSTRACT

Carrying cases are disclosed that include a tray for audio, computer, and/or video components. The tray can include a tray base member coupled to the case and a tray shelf that is movably coupled to the tray base member and configured to support a laptop or other audio, computer, or video component thereon. The tray shelf can be rotatable about a base axis defined by the tray base member, movable axially along the base axis, and/or rotatable about a tilt axis. In some embodiments, the tray base member can be secured to the case so that the base axis is generally stationary with respect to the case. The base axis can intersect the tray shelf, the top surface of the case, and/or the bottom surface of the case. In some embodiments, a hole can be positioned in a generally central portion of the tray shelf.

### BACKGROUND

1. Field

Embodiments of this disclosure relate to trays for audio, computer, and video components for use with carrying cases for transporting equipment such as mixers, controllers, amplifiers, or other music equipment.

2. Description of the Related Art

There exist a number of embodiments of carrying cases, some of which include a tray for supporting a laptop. Nevertheless, there remains a need for improved carrying cases.

### SUMMARY

An equipment case with integrated tray is disclosed. The equipment case can include a bottom case member having an open top, a closed bottom surface, and sidewalls and a top case member having an open bottom, a closed top surface, and sidewalls. The top case member and bottom case member can be configured to fit together to form an internal cavity. The case can include a tray shelf having a support surface configured to support a laptop or other piece of equipment. A tray base member can be coupled to the bottom case member, and the tray base member can define a base axis that intersects the tray shelf and the bottom surface of the bottom case member. The base axis can be substantially stationary with respect to the bottom case member. In some embodiments, the tray base member can be permanently secured to the bottom case member. The tray shelf can be rotatably coupled to the tray base member and configured to rotate about the base axis.

The tray shelf can be rotatable between a closed position and at least one open position, and the tray shelf can fit within the internal cavity of the equipment case when in the closed position and can extend outside an area of the internal cavity when in the at least one open position. In some embodiments, the tray shelf can be rotatable about the base axis across 360 degrees.

The tray shelf can have a hole through a generally central region of the tray shelf. The top case member can include at least one foam piece that is configured to fit through the hole in the tray shelf when the tray shelf is in a closed position and when the top case member is mounted onto the bottom case member.

The tray shelf can be coupled to a shaft that is slidably received by the tray base member so that the shaft and tray shelf are movable axially along the base axis between a lowered position and at least one raised position. The tray shelf can be attached to the shaft at a pivot point that allows the tray shelf to pivot about a second axis that is substantially orthogonal to the base axis. In some embodiments the shaft can rotate with the tray shelf about the base axis. The tray shelf can be configured to pivot about a second axis that is substantially orthogonal to the base axis such that the tray shelf is movable between a flat position and at least one angled position. In some embodiments, a tilt limiter can be configured to prevent rotation of the tray shelf past a predetermined range of rotation about the second axis. The tray shelf can be movable axially along the base axis between a lowered position and at least one raised position.

The tray shelf can include at least one support projection extending generally away from the support surface to prevent the laptop or other piece of equipment from sliding off the support surface. The base axis can be substantially orthogonal to the top surface of the top case member and/or substantially orthogonal to the bottom surface of the bottom case member.

The case can include one or more foam pieces on an underside of the tray shelf (e.g., removably attachable to the underside of the tray shelf) and configured to rest against a piece of equipment in the internal cavity when the tray shelf is in a closed position. The tray shelf can be removably coupled to the bottom case member such that the tray shelf can be removed from the bottom case member.

An equipment case with integrated tray is disclosed. The equipment case can include a bottom case member having an open top, a closed bottom surface, and sidewalls and a top case member having an open bottom, a closed top surface, and sidewalls. The top case member and bottom case member are configured to fit together to form an internal cavity. The case can include a tray shelf having a support surface configured to support a laptop or other piece of equipment. A tray base member can be coupled to the bottom case member, and the tray base member can define a base axis that intersects the tray shelf and the bottom surface of the bottom case member. The base axis member can be substantially stationary with respect to the bottom case member. In some embodiments, the tray base member can be permanently secured to the bottom case member. The tray shelf can be movable between a plurality of positions disposed about the base axis.

The tray shelf can fit within the internal cavity of the equipment case when in a closed position and can extend outside an area of the internal cavity when in an open position. The tray shelf can have a hole through a generally central region of the tray shelf. The top case member can include at least one foam piece that is configured to fit through the hole in the tray shelf when the tray shelf is in a closed position and when the top case member is mounted onto the bottom case member.

The tray shelf can be coupled to a shaft that is slidably received by the tray base member so that the shaft and tray shelf are movable axially along the base axis between a lowered position and at least one raised position. The tray shelf can be attached to the shaft at a pivot point that allows the tray shelf to pivot about a second axis that is substantially orthogonal to the base axis. The tray shelf can pivot about a second axis that is substantially orthogonal to the base axis such that the tray shelf is movable between a flat position and at least one angled position. In some embodiments, a tilt limiter can be configured to prevent rotation of the tray shelf past a predetermined range of rotation about the second axis. The tray shelf can be movable axially along the base axis between a lowered position and at least one raised position.

The tray shelf can include at least one support projection extending generally away from the support surface to prevent the laptop or other piece of equipment from sliding off the support surface. The base axis can be substantially orthogonal to the top surface of the top case member and/or substantially orthogonal to the bottom surface of the bottom case member.

The case can include one or more foam pieces on an underside of the tray shelf (e.g., removably attachable to the underside of the tray shelf) and configured to rest against a piece of equipment in the internal cavity when the tray shelf is in a closed position. The tray shelf can be removably coupled to the bottom case member such that the tray base member and tray shelf can be removed from the bottom case member.

A tray for use with an equipment case is disclosed. The tray can include a base member configured to be supported by the equipment case, and a shelf hingedly connected to the base member so that the shelf is movable between an open position and a closed position. The shelf can have a support surface that is exposed in the open position for supporting a laptop or other piece of equipment, the shelf having a hole through a generally central region of the shelf.

The tray can be used with an equipment case that includes a bottom case member having an open top and a top case member having an open bottom, and the top case member and bottom case member can be configured to fit together to form an internal cavity. The base member can be coupled to the equipment case. The bottom case member can include a first sidewall, a second sidewall opposite the first sidewall, a first rail extending upward from the first sidewall, and a second rail extending upward from the second sidewall. The base member can be coupled to the first rail and to the second rail so that the base member extends between the opposing first and second sidewalls. The first and second rails can include plurality of attachment points configured to receive the base member at a plurality of locations along the first and second rails.

The top case member can include at least one foam piece that is configured to fit through the hole in the shelf when the shelf is in the closed position and when the top case member is mounted onto the bottom case member. The shelf can be configured to fit within the internal cavity of the equipment case when in the closed position and to extend outside an area of the internal cavity when in the open position.

The shelf can include at least one support projection extending generally away from the support surface at a bottom of the shelf to prevent the laptop or other piece of equipment from sliding off the support surface. The base member can include at least one hole corresponding to the at least one support projection, an the support projection can extend through the hole in the base member when the shelf is in the closed position.

### BRIEF DESCRIPTION OF THE DRAWINGS

Certain embodiments will now be described in detail with reference to the following figures. These figures are provided for illustrative purposes only, and the inventions are not limited to the subject matter illustrated in the figures.

FIG. 1 is a perspective view of an example embodiment of a case having a tray incorporated therein with the tray in a closed position.

FIG. 2 is a perspective view of an example embodiment of a case with the tray in an open position.

FIG. 3 is an exploded perspective view of an example embodiment of a case having a tray incorporated therein.

FIG. 4 shows an example embodiment of a case with the top case component omitted and the tray in a closed position.

FIG. 5 shows an example embodiment of a case with the top case component omitted and the tray in an open position.

FIG. 6 shows an example embodiment of an open case with the tray omitted from view.

FIG. 7 is an exploded perspective view of an example embodiment of a tray.

FIG. 8 is a side view of an example embodiment of a tray shelf.

FIG. 9 is a side view of an example embodiment of a tray with the tray shelf in a first or flat position.

FIG. 10 is a side view of an example embodiment of a tray with the tray shelf in a second or tilted position.

FIG. 11 is a perspective view of an example embodiment of a tray with the tray shelf in a closed rotational position, a lowered axial position, and a flat tilted position.

FIG. 12 is a perspective view of an example embodiment of a tray with the tray shelf in an open rotational position, a lowered axial position, and a flat tilted position.

FIG. 13 is a top view of an example embodiment of a tray with the tray shelf having the position of FIG. 11 and showing the area of the internal cavity of a case.

FIG. 14 is a top view of an example embodiment of a tray with the tray shelf having the position of FIG. 12 and showing the area of the internal cavity of a case.

FIG. 15 is a perspective view of an example embodiment of a tray with the tray shelf in an open rotational position, a lowered axial position, and a tilted position.

FIG. 16 is a perspective view of an example embodiment of a tray with the tray shelf in an open rotational position, a raised axial position, and a flat tilted position.

FIG. 17 is a perspective view of an example embodiment of a case having a tray shelf in a closed position.

FIG. 18 is a perspective view of an example embodiment of a case having a tray shelf in an open position.

FIG. 19 is a close-up partial view of the case of FIG. 18.

### DETAILED DESCRIPTION

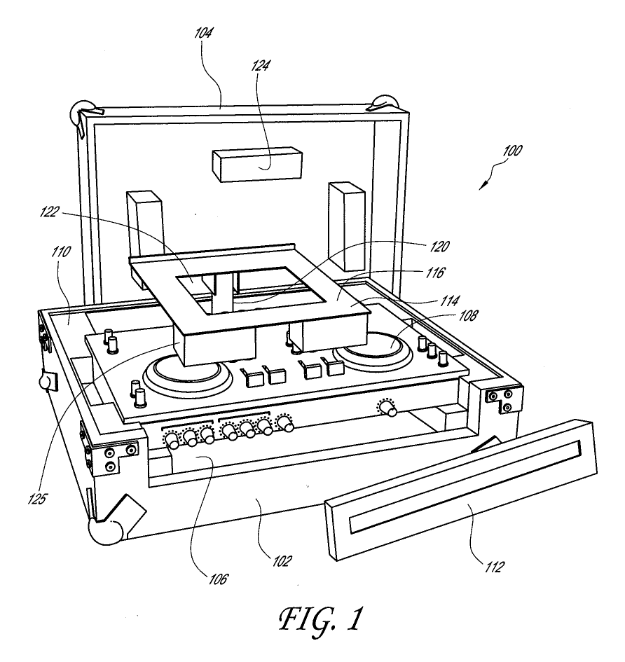

FIG. 1 is a perspective view of an equipment case 100 in an open configuration. The case 100 can include a bottom case member 102 and a top case member 104, which can fit together to form an internal cavity 106. The case 100 can be configured to receive equipment 108 therein such as a mixer, controller, amplifier, or other piece of music equipment. For example, the case can include one or more support structures 110 such as padding or foam blocks positioned inside the internal cavity 106 that can be shaped and configured to receive the equipment 108. In some embodiments, the equipment 108 can fit substantially snugly with the one or more support structures 110 in the case 100 so that the equipment does not shift significantly during transportation. The support structures 110 can include padding that lines the inside surfaces of the top and/or bottom case components 102, 104. The support structures 110 can be made from highly compressible materials such as open-cell foam, less compressible materials such as closed-cell foam, generally rigid materials such as plastics or wood, and/or combinations thereof to form the desired structure inside the case to accommodate and protect the equipment 108.

The case 100 can be rigid and configured to protect the equipment 108 contained in the internal cavity 106. Many shapes and configurations can be used for the case 100. For example, in the illustrated embodiment, the case 100 includes a removable front panel 112 that can be removed to expose features (e.g., knobs and/or buttons) of the equipment 108. In some embodiments, the case 100 can include additional case members, such as a central case member positioned between the bottom case member 102 and the top case member 104. Thus, the top case member 104 can be mounted onto the bottom case member 102 with one or more intermediate case members positioned therebetween. In some configurations, the case 100 can be divided into first and second side case components instead of top and bottom case components 104, 102. Many case configurations are possible, and because the case 100 is movable, the case components can be reoriented by the user. For example, in some configurations, the case components 102, 104 can be oriented as first and second side case components that are positioned side by side. As used herein, the bottom case component 102 can refer the piece of the case 100 to which a tray 114 is attached, regardless of the orientation of the bottom case component 102. In some embodiments, the bottom case component 102 can be configured so that the tray 114 is positioned in a usable orientation when the bottom case component 102 is positioned generally flat with the open side facing generally upward, as shown in FIG. 1.

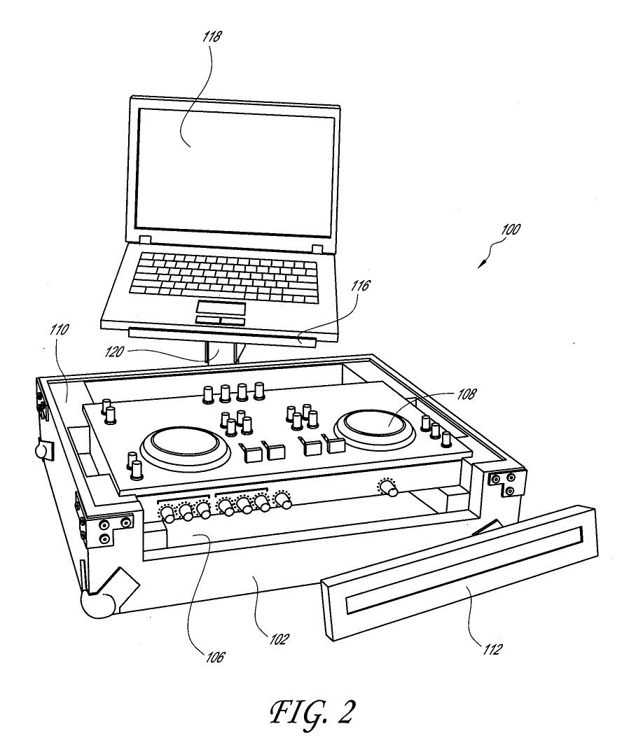

A tray 114 can be incorporated into the case 100. As can be seen in FIG. 2, the tray 114 can include a tray shelf 116, which can be configured to support audio, computer, or video components such as a laptop 118. A tray base 120 can couple the tray shelf 116 to the case 100, such as to the bottom case member 102. The tray shelf 116 can be oriented at multiple positions. In some embodiments, the tray shelf 116 can be rotatable with respect to the case 100, for example about the tray base 120. FIG. 1 shows the tray shelf 116 in a closed position such that the top case member 104 can be mounted onto the bottom case member 102 enclosing the tray 114 inside the internal cavity 106. In some embodiments, the closed position can be associated with a range of positions so that the tray shelf 116 can be rotated by an amount (e.g., a least about 1° and/or less than or equal to about) 10°) and remain in the closed position so long it fits into the internal cavity 106 when the case 100 is closed. FIG. 2 shows the tray shelf 116 in an open position such that the tray shelf 116 is positioned to prevent the top case member 104 from being mounted onto the bottom case member 102. Thus, in some embodiments, the tray shelf 116 can be positioned in the open position when the case 100 is open. In some embodiments, the tray shelf 116 can be oriented at various different open positions. Generally, when in use, the tray shelf is rotated so that the laptop 118 faces towards the front of the case (as shown for example in FIG. 2) where a user would generally be located, thereby making the laptop 118 accessible to the user. When in the open position for use, the tray shelf 116 can be rotated away from the closed position by at least about 100° and/or less than or equal to about 260°, or at least about 135° and/or less than or equal to about 225°, or at least about 170° and/or or about 190°, or about 180°.

In some embodiments, the top case member 104 can include one or more support structures 124, such as foam blocks, which can be configured to abut against or sit near the top surface of the equipment 108 to prevent the equipment 108 from shifting during transportation. The one or more support structures 124 (e.g., foam blocks) can be positioned such that they extend toward the bottom case member 102 without contacting the tray 114 when the tray 114 is in the closed position. For example, in the embodiment shown in FIG. 1, the case 100 includes three foam blocks 124 that are positioned around the periphery of the tray 114. In some embodiments, a foam block 124 or other support structure can be position so that it passes through the hole 122 of the tray 114 when the case 100 is closed. In some embodiments, one or more support structures 125 (e.g., foam blocks) can be positioned on a bottom surface of the tray shelf 116, which can be configured to rest against or sit near the top surface of the equipment 108 when the tray shelf 116 is in the closed position. Thus the support structures 125 can prevent the equipment 108 from contacting the tray shelf 116 and in some cases can prevent the equipment from shifting position during transportation. The support structures 124, 125 can be made of highly compressible materials, such as open-cell foam, so that the support structures 124, 125 can conform to the shape of the equipment 108 (e.g., to buttons and knobs that contact the support structures 124, 125), although closed-cell foams and other suitable materials can also be used in some embodiments.

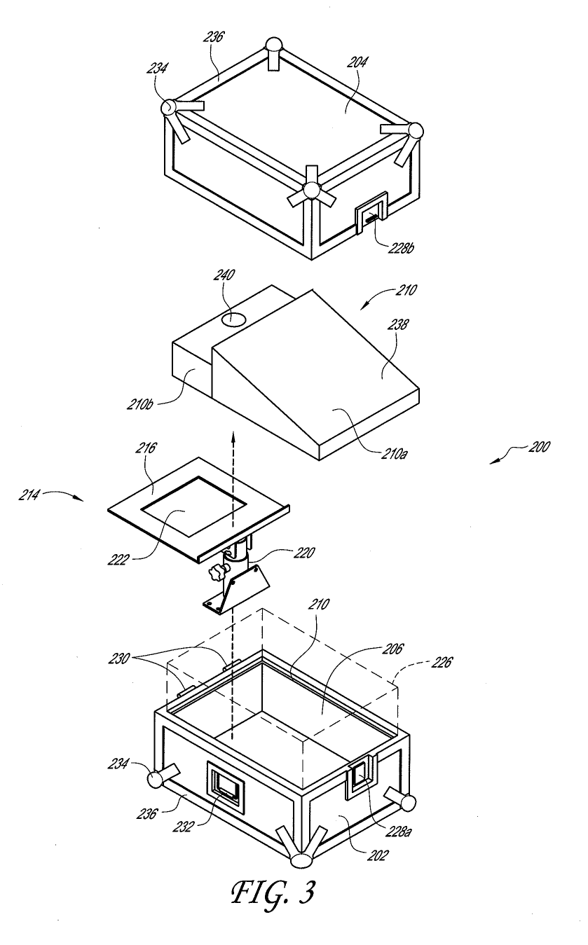

FIG. 3 is an exploded perspective view of a case 200 which can have features similar to, or the same as, the case 100 of FIG. 1. The top case member 204 can engage the bottom case member 202 to form an internal cavity 206. The area of the internal cavity 206 is shown in FIG. 3 by dotted line 226. One or more latches 228 can secure the top case member 204 to the bottom case member 202. In the illustrated embodiment a bottom latch element 228a is located on the bottom case member 202 and is configured to engage a top latch element 228b on the top case member 204. Hinge elements 230 on the top and bottom case members 202, 204 can interface to facilitate the attachment of the case members 202, 204. In some embodiments, the case 200 can include a handle 232. The top and/or bottom case members 202, 204 can include corner protective pieces 234 and/or edge protective pieces 236 configured to reinforce and protect the corners and/or edges of the case 100.

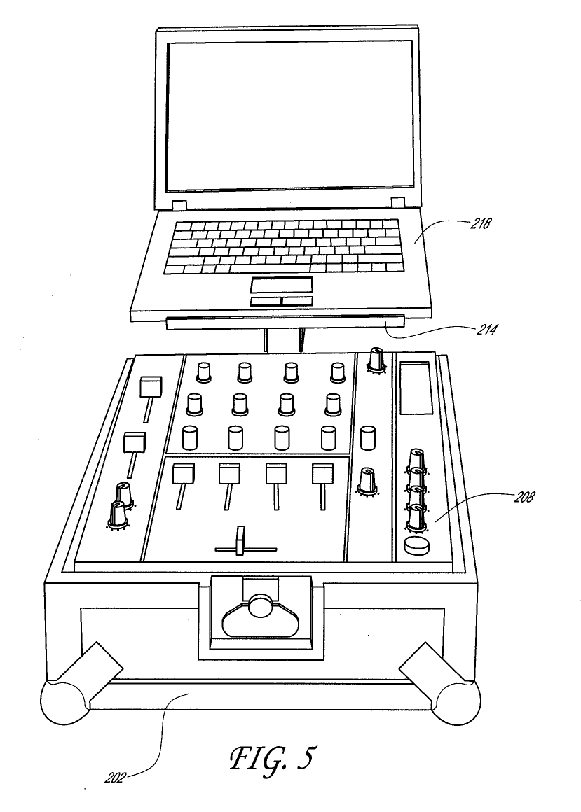

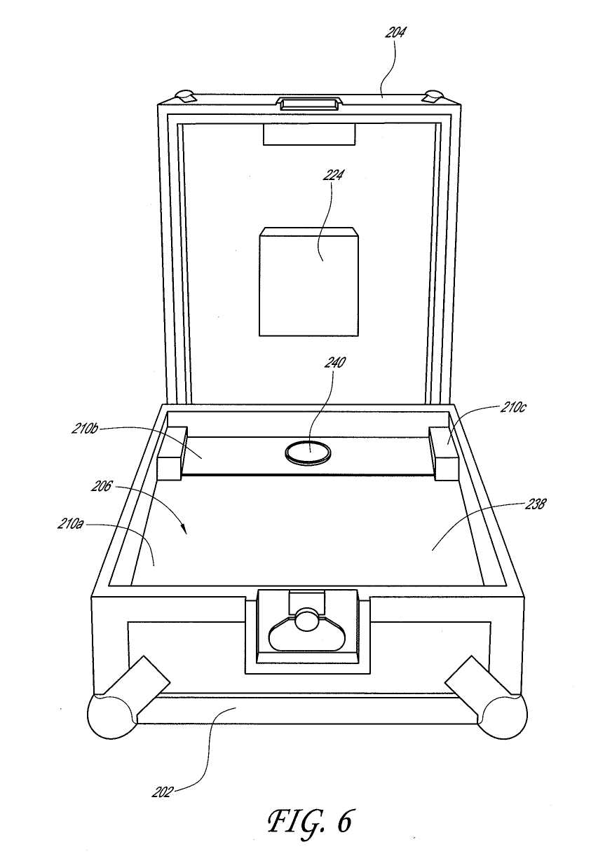

One or more support structures 210 can be positioned in the internal cavity 206. In the illustrated embodiment, the support structures 210 can provide an angled top surface 238, for example to angle the equipment 208 toward the user, as shown in FIG. 5. The support structures 210 can include padding that lines the inside surfaces of the top and/or bottom case components 202, 204. In some embodiments, the support structures 210 can include two parts 210a and 210b that can be separately formed or can be a unitary structure. A front portion 210a of the support structure 210 can have the angled surface 238 and a back portion 210b can have a hole 240. The support structures 210 can be made from materials similar to those described in connection with the support structures 110 above. In some embodiments, the support structures 210a, 210b can be made from a generally rigid material (e.g., wood or plastic) that provides the general shape of the support structures 210a, 210b, and they can be covered with padding (e.g., a closed-cell foam or a woven or carpet-like material). As can be seen in FIG. 6, some embodiments can include additional support structures 210c (e.g., closed-cell foam blocks) to modify the shape of the internal cavity 206 to accommodate the shape of the equipment 208 being inserted therein. The additional support structures 210c can be secured in place (e.g., using an adhesive) or can be movable. For example, the additional support structures 210c can have a coupling member that is configured to be attachable to multiple locations inside the case 200 to accommodate different shapes and sizes of equipment 208. The coupling member can be a Velcro type hook and loop fastener and at least a portion of the inside surface of the case 200 (e.g., the surface 238 and other surfaces) can be configured to receive the additional support structures 210c attached thereto (e.g., using corresponding Velcro type hook and loop fasteners).

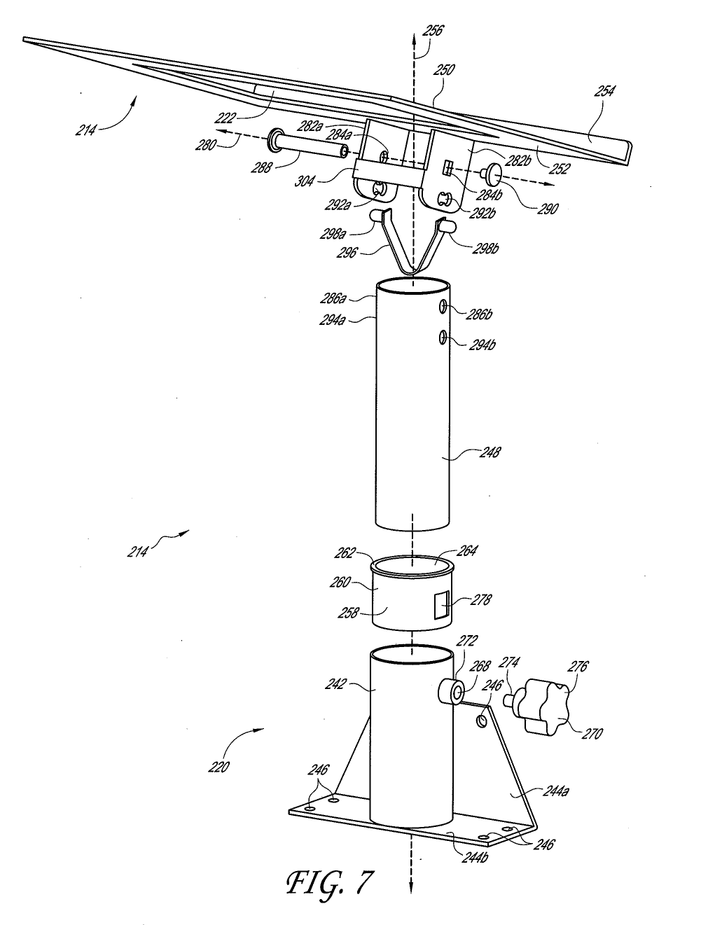

The case 200 can include a tray 214, which can be similar to, or the same as, the tray 114 described above. FIG. 3 shows the tray 214 as incorporated into the exploded view of the case 200. FIG. 7 is an exploded perspective view of the tray 214. A tray base 220 can be attached to the bottom case member 202. The tray base 220 can include a shelf attachment component 242 that is configured to support the tray shelf 216 and a case attachment component 244 that is configured to secure the tray base 220 to the case 200. The shelf attachment component 242 can be a base shaft that extends generally upwardly towards the tray shelf 216. The base shaft 242 can be generally cylindrical in shape and can be hollow to allow a shelf support shaft 248 to be inserted therein.

The case attachment component 244 can include one or more flanges or plates that are configured to attach to the case 200. For example, a first plate 244a can extend generally vertically so that it can lie against a side wall of the support structure 210a or against a side wall of the case 200. The first plate 244a can be welded or otherwise attached to the side of the base shaft 242. A second plate 244b can extend generally horizontally so that it can lie against the bottom of the case 200, and the second plate 244b can be welded or otherwise attached to the bottom surface of the base shaft 242. In some embodiments, only a single plate can be used, or additional case attachment members can be used in addition to those shown in the illustrated embodiment. The plates 244 can include through holes 246 so that the tray base 220 can be secured to the case 200 using screws or bolts that pass through the through holes 246. The tray base 220 can be secured to the case 200 in other manners, such as using an adhesive, clamps, welding, a friction fitting, or any other suitable attachment mechanism. The tray base 220 can be attached directly to the bottom case member 202 or can be attached to a component that is coupled to the case 200. For example, the tray base 220 can be secured to the front support structure 210a, for example by screws through the through holes in the first plate 244a. In the assemble configuration, the base shaft 242 can extend up through the hole 240 formed in the support structure 210b.

The tray 214 can include a tray shelf 216, which can include an upper surface 250 and a bottom surface 252. The tray shelf 216 can be configured to support audio, computer, or video components such as a laptop 218 on the upper surface 250 thereof. Although some embodiments are described as being used with a laptop 218, various other pieces of audio, computer, or video equipment could be used in place of the laptop 218. In some embodiments, the upper surface 250 of the tray shelf 216 can include a slide-resistant surface, such as a closed-cell foam that covers at least a portion of the upper surface 250, to prevent the laptop 218 (or other piece of equipment) from sliding off of the tray shelf 216. In some embodiments, one or more support projections 254 can extend away from the upper surface 250 at an end or edge of the tray shelf 216, and can be configured to prevent the laptop 218 from sliding off the tray 214. For example, when the tray shelf 216 is in an angled position (as discussed elsewhere herein), gravity can pull the laptop 218 downward toward the end of the tray 214 that has the support projection 254, and the laptop 218 can abut and press against the support projection 254 to prevent the laptop 218 from sliding off the tray shelf 216. The support projection 254 and/or the slide-resistant covering can also reduce sliding of the laptop 218 that can result from movement of the tray 214 during use, for example, when repositioning the orientation of the tray 214 or when the case 200 is bumped or moved during use.

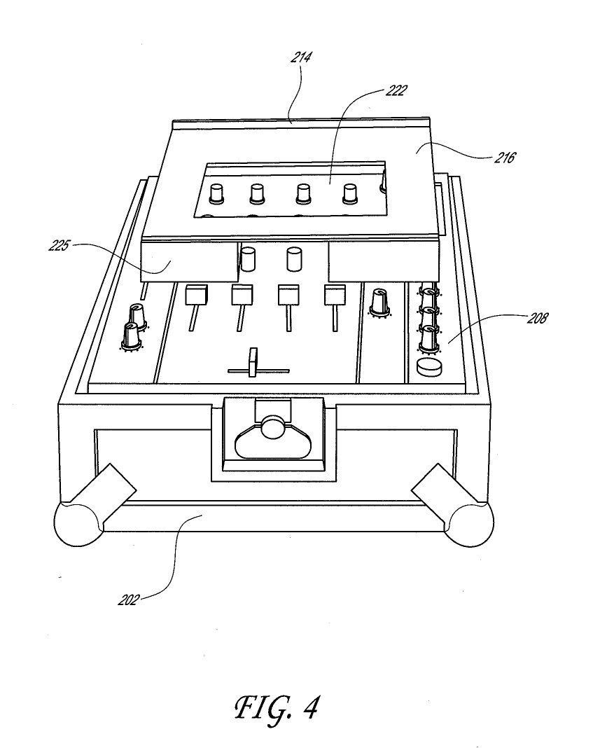

In some embodiments, the bottom surface 252 of the tray shelf can include a covering that is configured to facilitate attachment of one or more support structures 225 (e.g., open-cell foam blocks) thereto. For example, the bottom surface 252 can be covered at least in part by a Velcro type hook and loop fastener material. As shown in FIG. 4, foam blocks 225 can be attached to the bottom surface 252 of the tray shelf 216, for example, by Velcro type hook and loop fastener components that are attached to the foam blocks 225 and correspond to the fastener material on the bottom surface 252. Thus, the foam blocks 252 can be removed (e.g., when the tray is in use with a laptop 218), and can also be repositioned or interchanged with foam blocks of different sizes or shapes (e.g., depending on the shape of the equipment 208). The foam blocks 252 can be configured to extend down to rest against or near the equipment 208. The one or more foam blocks 252 can be compressible so as to conform to the structure of the equipment 208 (e.g., knobs and buttons, etc.) In the embodiment shown in FIG. 4, two foam blocks 252 are included, but a single piece of foam, or any other suitable number of foam pieces, can be used. In some embodiments, the foam blocks 225 can be permanently or semi-permanently attached to the tray shelf 216, for example, by an adhesive.

In some embodiments, the top case member 204 can include one or more support structures 224, such as foam blocks. The foam blocks 224 can be configured to extend down toward and rest against or near the top surface of the equipment 208 to prevent the equipment 208 from shifting during transportation. The foam blocks 224 can be removably attachable to the top case member 204, or they can be permanently or semi-permanently attached thereto. In some embodiments, the foam block 224 can be position so that it passes through a hole 222 formed in the tray shelf 216 when the case 200 is closed. The hole 222 formed in the tray shelf 216 can also provide for venting or air flow to and from the underside of the laptop 218 to prevent the laptop 218 from overheating.

The tray shelf 216 can be oriented at multiple positions relative to the tray base 220. In some embodiments, the tray shelf 216 can be rotatable with respect to the tray base 220. For example, the tray shelf 216 can be coupled to a shelf support shaft 248, which can be rotationally coupled to the base shaft 242 of the tray base 220. The outer diameter of the shelf support shaft 248 can be slightly smaller than the inner diameter of the base shaft 242 so that the shelf support shaft 248 can telescope into the base shaft 242. The inner surface of the base shaft 242 and the outer surface of the shelf support shaft 248 can have corresponding circular cross sectional shapes so that the shelf support shaft 248 can rotate inside the base shaft 242 about a base axis 256.

The base axis 256 can extend generally along a centerline through the generally cylindrical shape of the base shaft 242 and/or along a centerline through the generally cylindrical shape of the shelf support shaft 248. The base axis 256 can intersect the tray shelf 216, the bottom surface of the bottom case member 202, and/or the top surface of the top case member 204 (when mounted onto the bottom case member 202 in the closed case configuration). The base axis 256 can be generally orthogonal to the tray shelf 216 (when in the flat tilted position), the bottom surface of the bottom case member 202, and/or the top surface of the top case member 204 (when mounted onto the bottom case member 202 in the closed case configuration). In some embodiments, the base axis 256 can be offset from the direction orthogonal to the tray shelf 216 (when in the flat tilted position), the bottom surface of the bottom case member 202, and/or the top surface of the top case member 204 (when mounted onto the bottom case member 202 in the closed case configuration) by some angle, such as by less or equal to about 15°, 10°, or 5°. In some embodiments, the tray base 220 can be secured to the case 200 such that the base axis 256 is substantially stationary with respect to the bottom case member 202 and/or the case 200. Thus, in some embodiments, the base axis 256 does not move substantially with respect to the base case member 202 and/or the case 202. The stationary base axis 256 can allow for a simpler and more durable construction as compared to more complicated designs having a rotation axis defined by a moving component that is not secured to the case. In some embodiments, the tray shelf 216 is rotatable about a single vertical axis 256, which can also provide a simple and durable construction as compared to a tray that rotates about multiple vertical axes.

In some embodiments, a shaft insert 258 can be positioned in the base shaft 258. The shaft insert 258 can include a generally cylindrical body 260 configured to fit inside the base shaft 242, and a flange 262 that is wider than the inner diameter of the base shaft 242 to prevent the shaft insert 258 from being fully received into the base shaft 242. A step formed by the flange 262 can rest against or near the top surface of the base shaft 242. The shaft insert 258 can have an inner surface 264 that is configured to receive the shelf support shaft 248 therein. In some embodiments, the shafts 242, 248 can be made from metal, and the shaft insert 258 can be made from a plastic or other material different from the shafts 242, 248. The shaft insert 258 can be made from a material, or applied with a coating, that facilitates movement of one or both of the shafts 242, 248 against the shaft insert 258. Thus, the shaft insert 258 can facilitate the rotational movement of shelf support shaft 248 with respect to the base shaft 242 about the base axis 256 and/or the axially slidable movement of the shelf support shaft 248 with respect to the base shaft 242 along the base axis 256.

In some embodiments, the shaft insert 258 can be configured to create friction against the base shaft 242 and/or against the shelf support shaft 248 to prevent the shafts 242, 248 from unintentionally shifting in position relative to each other. Thus, a user can adjust the tray shelf 216 to a desired position and release the tray shelf 216, and the shaft insert 258 can prevent the shelf support shaft 248 from shifting in position unintentionally with respect to the base shaft 242 (e.g., due to gravity pulling the shafts 242, 248 into a further telescoped position, or due to bumping or moving of the case during use). The shaft insert 258 can provide friction that prevents movement of the shelf support shaft 248 with respect to the base shaft 242 up to a threshold level of force, and if force greater than the threshold is applied, the shelf support shaft 248 is permitted to move with respect to the base shaft 242.

In some embodiments, the tray shelf 216 can be rotatable across a full 360° about the base axis 256 with respect to the base shaft 242, and the tray shelf 216 can be rotated in multiple revolutions in a single direction. The tray shelf 216 can be rotationally oriented at any arbitrary position selected across an available range of motion (e.g., 360°). The shelf support shaft 248 can be slidably coupled to the base shaft 242 so that the tray shelf 216 can be movable axially along the base axis 256 with respect to the tray base 220. The tray shelf 216 can be axially positioned at any arbitrary location selected along the available axial range of motion between the base shaft 242 and the shelf support shaft 248. Thus, the tray 214 can provide a wide range of freedom to the user for positioning and orienting the laptop 218 with respect to the case 200.

The tray 214 can include a selective movement limiter 266, which can selectively limit or prevent rotational and/or axial movement of the tray shelf 216 with respect to the tray base 220. For example, in the embodiment shown in FIG. 7, the base shaft 242 can include a threaded bore 268 which can receive a locking screw 270 therein. A projection 272 can extend out from the side surface of the base shaft 242 and the threaded bore 268 can extend through the projection 272 and through the side wall of the base shaft 242 so that the bore 268 has a length greater than the thickness of the side wall of the base shaft 242. The locking screw 270 can include a threaded shaft 274 configured to be threaded into the bore 268 and a knob 276 to facilitate rotation of the screw 270. The screw 270 can be advanced in the treaded bore 268 so that the end of the screw shaft 274 presses against the side wall of the shelf support shaft 248, thereby limiting or preventing movement of the shelf support shaft 248 with respect to the base shaft 242. In some embodiments, the additional friction caused by the screw 270 pressing against the shelf support shaft 248 can increase the threshold level of force needed to move the tray shelf 216, but can still allow movement of the tray shelf 216 if force above the increased threshold level is applied. By tightening and loosening the screw 270, the user can adjust the threshold level of force needed to move the tray shelf 216. In some embodiments, the screw 270 can interface with features (e.g., holes formed in the shelf support shaft 248) to substantially lock the tray shelf 216 in place. The holes in the shelf support shaft 248 (or other locking features) can define one or more lockable positions for the tray shelf 216. In some embodiments, the shaft insert 258 can include an opening 278 configured to align with the threaded bore 268 to allow the screw shaft 274 to pass through the shaft insert 258 and contact the shelf support shaft 248 directly. In some embodiments, the shaft insert 258 does not include the opening 278 and the screw shaft 274 can press against the outside surface of the shaft insert 258 causing the inside surface of the shaft insert 258 to press against the shelf support shaft 248 to limit movement of the tray shelf 216.

The tray shelf 216 can be movable between multiple tilted positions. For example, the tray shelf 216 can be rotatable about a tilt axis 280 with respect to the shelf support shaft 248, to the tray base 220, and/or to the case 200. The tilt axis 280 can be generally orthogonal to the base axis 256, or the tilt axis 280 can be offset from the direction orthogonal to the base axis 256 by some angle, such as by less or equal to about 15°, 10°, or 5°. As can be seen in FIG. 7, a pair of extensions 282a, 282b can extend from the bottom surface 252 of the tray shelf 216. Holes 284a and 284b can be positioned on corresponding extensions 282a, 282b and can align with the tilt axis 280. When assembled, the holes 284a, 284b can also align with holes 286a, 286b formed in the shelf support shaft 248 so that a bolt 288 can pass through the extension piece 284a, through the side walls of the shelf support shaft 248, and through the extension piece 284a. A nut 290 can be attached to the end of the bolt 288 to secure it in place. In the exploded view of FIG. 7 the tilt axis 280 is shown aligned with the bolt 288 which forms the pivoting axis for tilting the tray shelf 216, and in the assembled (not exploded) configuration the tilt axis 280 can also align with the holes 286a, 286b.

The tray shelf 216 can be configured to be movable between multiple positions about the tilt axis 280. In the illustrated embodiment, the tray shelf is configured to be movable about the tilt axis 280 between two positions, but in some embodiments, three, four, five, or more tilt positions can be available. Holes 292a, 292b can be formed in the extensions 282a, 282b, and the holes 292a, 292b can align with holes 294a, 294b in the shelf support shaft 248 when assembled. Biased pins 298a, 298b can be used to lock the tray shelf 216 into a particular position on the tilt axis 280. The pin 298a can be configured to extend through the holes 294a and 292a, and the pin 298b can be configured to extend through the holes 294b and 292b. A spring element 296, which can be a bent bow spring placed inside the shelf support shaft 248 with the pins 298a, 298b, can be configured to bias the pins 298a, 298b radially outwardly through the corresponding holes 294a and 292a, or 294b and 292b. Although the illustrated embodiment has two pins 298a, 298b and two corresponding holes 292a, 292b, a single pin 298 and a single hole 292 can be used.

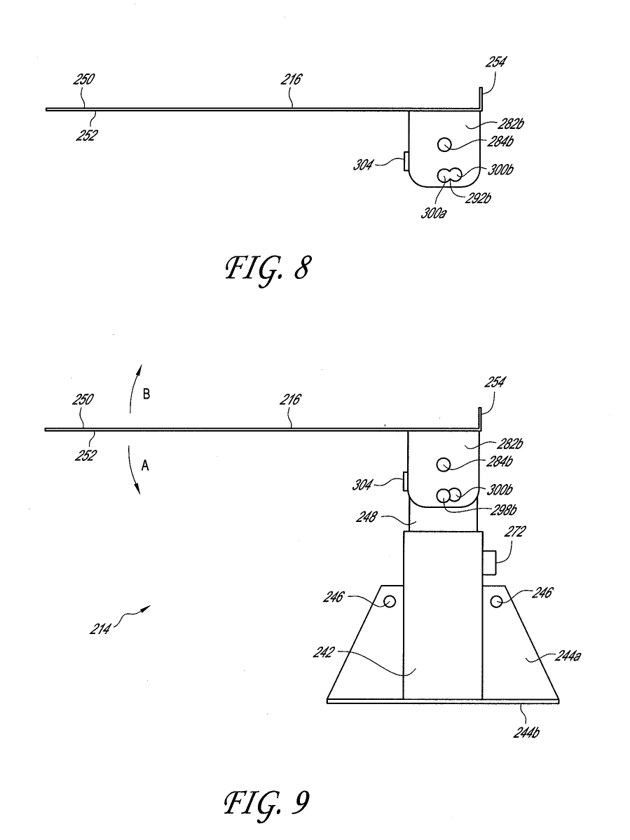

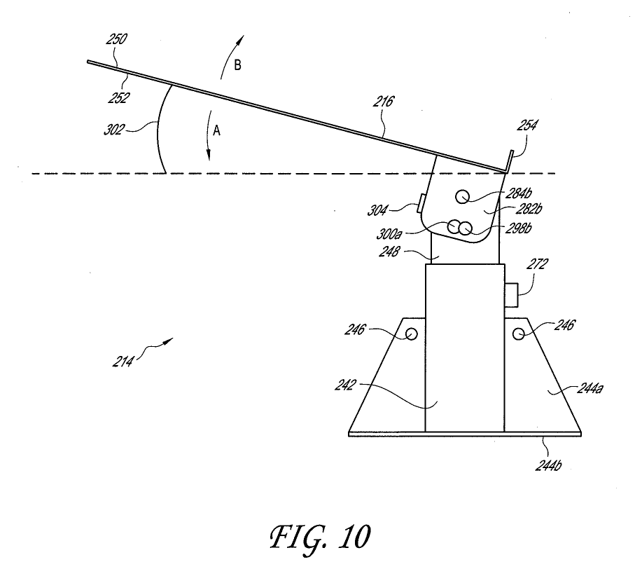

FIG. 8 is a side view of the tray shelf 216. FIG. 9 is a side view of the tray 214 with the tray shelf 216 positioned in a flat orientation. FIG. 10 is a side view of the tray 214 with the tray shelf 216 in a tilted position. As shown in the figures, the hole 292b can have two portions 300a and 300b separated by a narrow region therebetween, so that the corresponding pin 298b can selectively engage the first portion 300a or the second portion 300b of the hole 292b. The other hole 292a and pin 298a can function similar to the hole 292a and pin 298b. In the illustrated embodiment, when the pin 298b is engaged with the first portion 300a of the hole 292b, the tray shelf 216 can be in a first position, which can be a flat position, as shown in FIG. 9. When the pin 298 is engaged with the second portion 300b of the hole 292b, the tray shelf 216 can be in a second position, which can be angled with respect to the horizontal plane, as shown in FIG. 10. When in the second position, the tray shelf 216 can be positioned at an angle 302 with respect to the horizontal plane and/or with respect to the first position, and the angle 302 can be at least about 5° and/or less than or equal to about 25°, or at least about 10° and/or less than or equal to about 20°, or about 15°.

To move the tray shelf 216 between tilted positions about the tilt axis 280, the pins 298a, 298b can be pushed inward against the radially biasing force produced by the spring 296 until the pins 298a, 298b clear the holes 292a, 292b enough for the tray shelf 216 to pivot about the axis 280. The tray shelf 216 can be pivoted about the tilt axis 280 until the pins 298a, 298b align with the desired portion 300a or 300b of the holes 292a, 292b, and the pins 298a, 298b can be released so that they engaged the desired portion 300a or 300b of the holes 292a, 292b to secure the tray shelf 216 in the desired tilted position.

The tray 214 can include a tilt limiter 304 that is configured to prevent the shelf tray 216 from being tilted beyond the desired range of motion about the tilt axis 280. The tilt limiter 304 can be a bar extending between the extension elements 282a, 282b on one side. If the tray shelf 216 is urged downward in the direction shown by arrow A from the first, or flat position of FIG. 9, the bar 304 can abut against a portion of the shelf support shaft 248 to prevent the tray shelf 216 from rotating in direction A significantly past the first, or flat position of FIG. 9. Similarly, if the tray shelf 216 is urged upward in the direction shown by arrow B from the second position of FIG. 10, the bar 304 can abut against a higher portion of the shelf support shaft 248 to prevent the tray shelf 216 from rotating in direction B significantly past the second position of FIG. 10.

The tray shelf 216 can be oriented at multiple rotational positions about the base axis 256, can be positioned at multiple axial locations along the base axis 256, can be oriented as multiple tilted positions about the tilt axis 280, and/or any combination there of. In some embodiments, the tray shelf 216 can be rotatable about the base axis 256, and can be lockable at any position in the available rotational range of motion, which can be a full 360°. The tray shelf 216 can be slidable axially along the base axis 256, and can be lockable at any position in the available axial range of motion. The tray shelf 216 can be rotatable about the tilt axis 280, and can be lockable at a finite number of predetermined positions about the tilt axis 280.

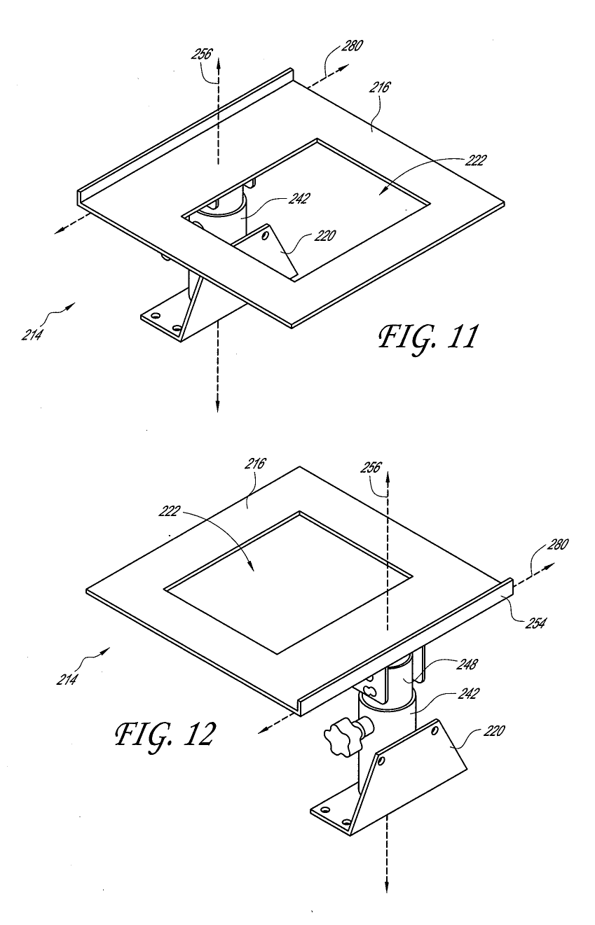

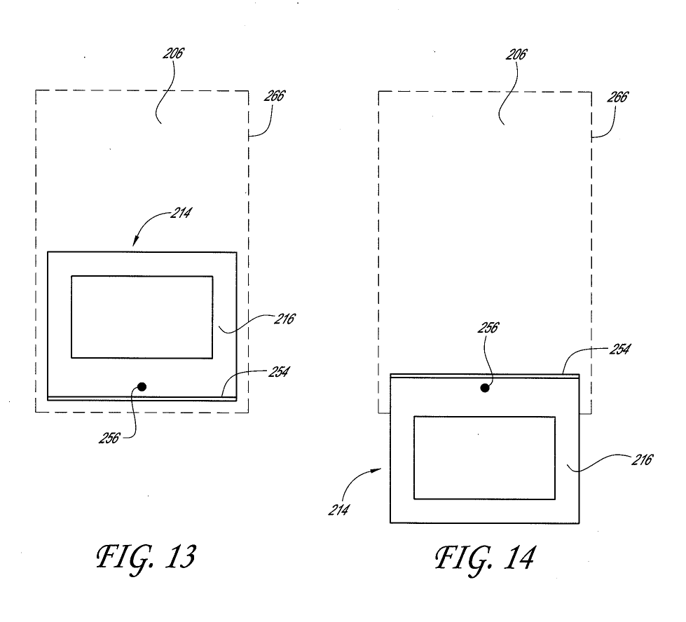

FIG. 11 is a perspective view of the tray 214 shown in an assembled configuration and with the case 200 omitted from view. In FIG. 11, the tray shelf 216 is in a closed rotational position, in a lowered axial position, and in a flat tilted position. In some embodiments, the configuration of FIG. 11 positions the tray 214 in a compact configuration that allows the tray 214 to fit inside the internal cavity 206 of the case 200 when closed. FIG. 13 shows a top view of the tray 214 in same closed, lowered, flat position of FIG. 11 with the area 266 of the internal cavity 206 is shown by a dotted line. In the closed, lowered, and flat positions, the tray shelf 216, and the rest of the tray 214 can be contained completely inside the area 266 of the internal cavity 206, and can occupy only available space inside the case 200 that is not occupied by equipment 208 or support structures 210 or other components. Thus, the case 200 can be closed for transportation with the tray 214 and the equipment 208 contained inside the internal cavity 206 when the tray shelf 216 is in the closed, lowered, and flat configuration. As can be seen in FIGS. 1, 4, and 13, when in the closed rotational position, the tray shelf 216 can cover a significant portion of the internal cavity 206, and can cover the equipment 208 so that the equipment is not readily usable. Also, if a laptop 218 is positioned with the front of the laptop 218 facing towards the support projection 254, the screen would face away from the user towards the back of the case 200 when the tray shelf is positioned as shown in FIGS. 11 and 13. Thus, the closed rotational position can generally be considered a non-use position.

FIG. 12 shows the tray shelf 216 in an open rotational position that is offset from the closed position of FIG. 11 by about 180° about the base axis 256. The tray shelf 216 in FIG. 12 is also in a lowered axial position and in a flat tilted position. FIG. 14 shows a top view of the tray 214 in the same open, lowered, and flat configuration of FIG. 12, with the area 266 of the internal cavity 206 shown by the dotted line. In the open rotational position, the tray shelf 216 extends outside the area 266 of the internal cavity 206, thereby preventing the case 200 from being closed. As shown in FIGS. 2, 5, and 14, when in the open rotational position, the tray shelf 216 can be substantially clear of the equipment 208 contained inside the case 200, and can face a laptop 218 on the tray shelf 216 toward the user so that the laptop 218 and equipment 208 can be accessible to the user simultaneously. Thus, the open rotational position can generally be considered a ready-for-use position.

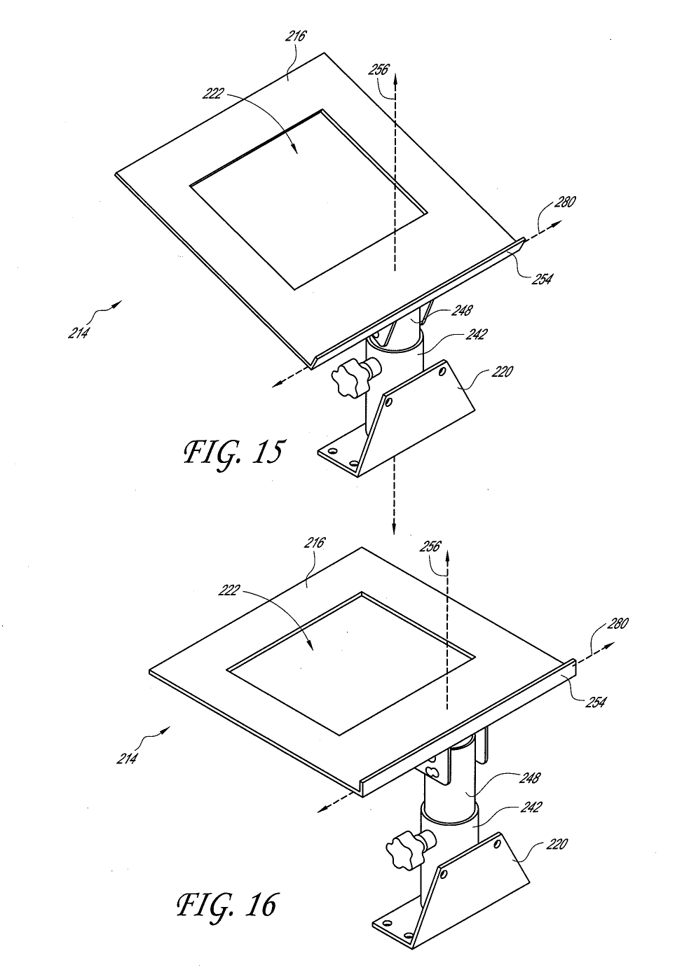

FIG. 15 shows the tray shelf in an open rotational position, a lowered axial position, and an angled tilted position that is offset from the flat tilted position by about 15° about the tilt axis 280. The angled position can make the laptop 218 more accessible for the user. FIG. 16 shows the tray shelf in an open rotational position, a raised axial position, and a flat angled position. The raised axial position can position the laptop 218 in a more accessible position for the user and can also provide better clearance from the equipment 208 in the case thereby making the equipment 208 more accessible to the user. The range of axial movement can vary depending on the height of the case 200 and the amount of telescoping overlap between the base shaft 242 and the shelf support shaft 248. In some embodiments, the tray shelf 216 can be axially movable across a range of at least about 1 inch and/or less than or equal to about 8 inches, or at least about 3 inches and/or less than or equal to about 6 inches, or about 4½ inches. In some embodiments, the upper surface 250 of the tray shelf 216 can face generally upwardly across the full range of motion in each movable direction and in all combinations of positions.

In some cases the tray shelf 216 can be removably coupled to the bottom case member 202 so that the tray shelf 214 can be removed and transported outside the case 200. For example, the tray shelf 216 can be pulled axially upwardly from the raised axial position of FIG. 16 until the shelf support shaft 248 is separated from the base shaft 242. The removable tray shelf 216 can be used with a case of small size having an internal cavity that is not large enough to receive the tray shelf 216 inside the internal cavity when the case is closed, or with a case having large equipment stored therein so that the internal cavity has insufficient space to accommodate the tray shelf 216 when the case is closed with the large equipment therein.

Many variations can be made to the illustrated embodiments. For example, the holes 292a, 292b can have more than two portions 300a, 300b so that the tray shelf 216 is movable between more than two positions, such as three, four, five, or more tilt positions. In some embodiments, separate holes an be used for the different tilt positions instead of holes 292a, 292b having connected hole portions 300a, 300b. However, the connected hole portions 300a, 300b can be beneficial to allow movement between tilt positions without pushing the pins 298a, 298b completely in past the walls of the extension elements 282a, 282b, which can be difficult or uncomfortable for the user and/or can cause the pins to unintentionally disengage from the holes 294a, 294b and become stuck inside the shelf support shaft 248. Also, the holes 292a, 292b, or other aspects of the tray 214, can be modified so that the tray shelf 216 is movable across different angles than those shown, and lockable at different angles than those shown. For example, the tray 214 can be configured so that the tray shelf 216 is not lockable at a flat position (as in FIG. 9) that is generally parallel with the horizontal plane. However, the flat configuration of FIG. 9 can be beneficial to allow the tray shelf 216 to fit into the allocated space inside the case 200 when the case 200 is closed. Other case configurations may use other, non-flat, angles to fit the tray shelf 216 into the closed case 200.

In some embodiments, a screw similar to 270 can be used in connection with a threaded bore similar to 268 but on the tray shelf 216 to allow the user to selectively tighten and loosen the screw to adjust the amount of force required to change the tilt position of the tray shelf 216. The screw and bore can be used, similarly to the screw 270 and bore 268, to allow the tray shelf 216 to be oriented at any arbitrary position selected inside the available range of motion about the axis 280.

Also, the rotation about the base axis 256 and axial movement can be controlled by biased pins (similar to the pins 298a, 298b) inside the lower portion of the shelf support shaft 248 that are configured to engage a plurality of holes in the base shaft 242. The holes in the base shaft 242 can be positioned at various locations axially and about the circumference of the base shaft 242 to provide various corresponding axial and rotational locking positions for the tray shelf 216.

Also, the shelf support shaft 248 can be made wider than the base shaft 242 so that the base shaft 242 is received into the shelf support shaft 248. Thus, some of the structure and functionality can be interchangeable between the shelf support shaft 248 and the base shaft 242. One or both of the shafts 242, 248 can have a non-circular cross-sectional shape. For example, the base shaft 242 can have a polygon shaped cross section and the shelf support shaft 248 can have a corresponding polygon shaped cross section, so that the shelf support shaft 248 and the base shaft 242 can fit together in a finite number of predetermined positions about the base axis 256. For example, if the base shaft 242 and the shelf support shaft 248 have octagon shaped cross sections, they can fit together at eight different positions about the base axis 256, where each position is offset by about 45° from the adjacent positions. Various other cross sectional shapes can be used.

In some embodiments, the tray base member 220 can be integrated into the case 200. Thus, movement described a being with respect the tray base member 220 can also be with respect to the bottom case member 202 or the case itself 200. Descriptions of one component being movable with respect to an identified component should be understood to also be movable with respect to other components coupled to the identified component even if the other components are not specifically identified in connection with the movement.

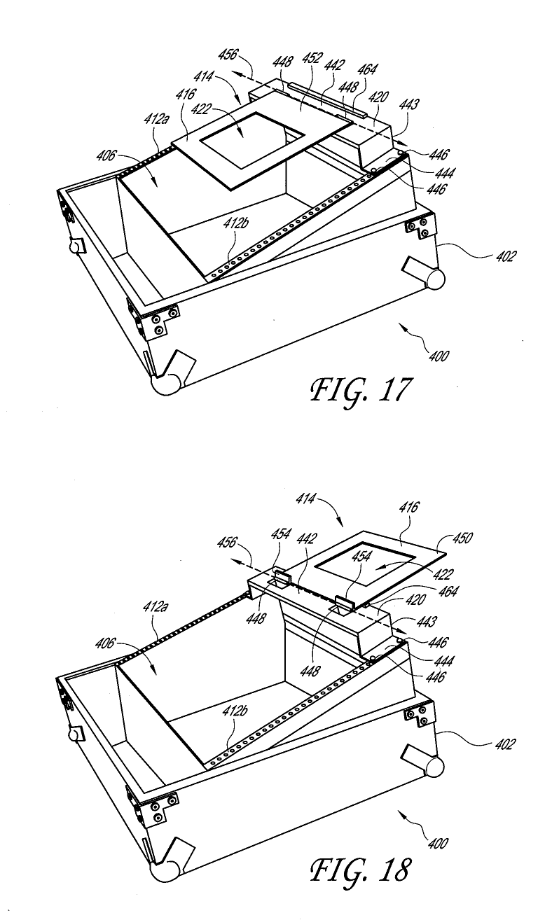

FIG. 17 is a perspective view of another embodiment of a carrying case 400 having a tray shelf 416 in a closed position. FIG. 18 is a perspective view of the carrying case 400 with the tray shelf 416 in an open position. The case 400 can have features that are similar to, or the same as, the other cases (e.g., 100 and 200) disclosed herein. The case 400 can include a bottom case member 402 and a top case member (not shown), which can define an internal cavity 406. The internal cavity 406 can be configured to hold equipment (not shown) such as music equipment. The case 400 can include various support structures 410 similar to those described above, which can pad the inside of the case 400 can provide for a snug fitting with the equipment.

The case 400 can include a pair of rails 412a, 412b, which can be positioned on opposing sides of the case 400. The first rail 412a can extend upward from a first side wall of the bottom case member 402, and the second rail 412b can extend upward from a second side wall of the bottom case member 402. The rails 412a, 412b can be angled so that they extend upward away from the bottom case member 402 by a greater distance at the back of the case 400 than at a front side of the case 400, and in some embodiments, the rails 412a, 412b are flush with, or below, the top of the bottom case member 402 at the end of the rails 412a, 412b closest to the front of the case 400. The rails 412a, 412b can include a plurality of holes or other attachment features configured to allow components to be mounted onto the rails 412a, 412b at various positions along the rails 412a, 412b.

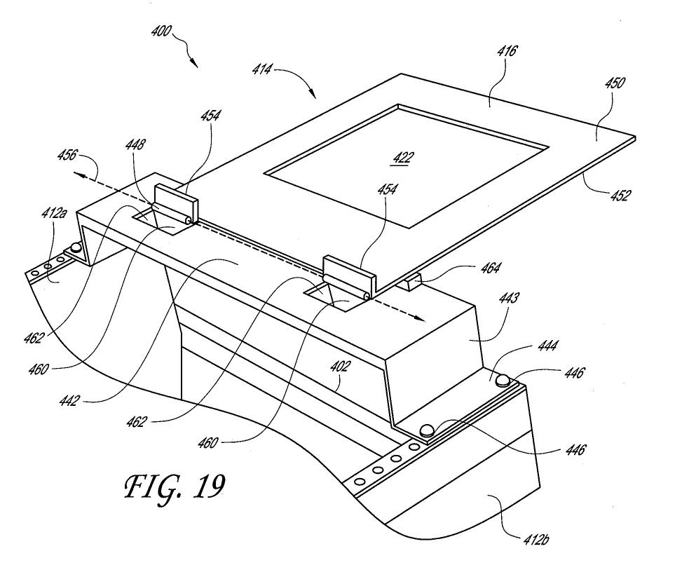

The case 400 can include a tray 414 that has a tray shelf 416 moveable with respect to the bottom case member 402 between a closed position (FIG. 17) and an open position (FIG. 18). FIG. 19 is a close-up partial view of the case 400 of FIG. 18. A tray base member 420 can be mounted onto the rails 412a, 412b and can extend between the rails 412a, 412b and across the internal cavity 406. The base member 420 can extend linearly between the rails 412a, 412b, or it can have a raised center portion 442, as shown in FIGS. 17 and 18. The raised central portion 442 can have steps 443 on either side that lead to attachment flanges 444 having holes 446 configured to align with holes on the rails 412a, 412b so that screws or bolts can secure the base member 420 to the rails 412a, 412b. In the illustrated embodiment, the base member 420 is positioned near the back of the case 400 so that the internal cavity 406 is left mostly uncovered when the tray shelf is in the open position (FIG. 18), thereby providing access to the equipment (not shown) inside the internal cavity 406.

One or more hinge mechanisms 448 can couple the tray shelf 416 to the tray base member 420 so that the tray shelf 416 is hingedly coupled to the tray base member 420 so that the tray shelf can rotate about an axis 456 between a closed position, shown in FIG. 17, and an open position, shown in FIG. 18. The axis 456 can be oriented so that it intersects opposing side walls of the case 400. In the illustrated embodiment, the axis 456 intersects the side walls of the top case member (not shown). The hinge mechanisms 448 can be bolted or otherwise attached to projections 460 that extend downward from holes 462, and to the bottom side 452 of the tray shelf 416 at or near the bottom of the tray shelf 416.

The tray shelf 416 can be configured to support a laptop or other piece of equipment on the upper surface 450 thereof, when in the open configuration, shown in FIGS. 18 and 19. The tray shelf 416 can include one or more support projections 454 configured to prevent a laptop from sliding off the tray shelf 416 similar to the other support projections described herein. The top surface 450 can also include a slide-resistant surface. The base member 420 can include one or more holes 462 that can be aligned with the one or more support projections 454 so that the support projections 454 can pass through the holes 462 when the tray shelf 416 is in the closed position, shown in FIG. 17. The holes 462 can allow the tray shelf 416 to be more compact in the closed position so that the tray shelf 416 can fit into the area of the internal cavity 406 to allow the case 400 to be closed with the tray 414 and equipment (not shown) contained therein. When in the open position, the tray shelf 416 can extend outside the area of the internal cavity 406 and can be positioned to cover little of the internal cavity to provide access to the equipment positioned in the internal cavity during use. In the closed configuration, the bottom surface 452 of the tray shelf 416 can face generally upwardly, and in the open configuration, the top surface 450 of the tray shelf 416 can face generally upwardly.

The tray shelf 416 can have a hole 422 positioned generally in the central portion thereof. In some embodiments, at least one foam block (not shown) can be position on the top case member so that it passes through a hole 422 formed in the tray shelf 416 when the case 400 is closed, in a manner similar to that discussed in connection with the other embodiments disclosed herein. The hole 422 formed in the tray shelf 416 can also provide for venting or air flow to and from the underside of the laptop to prevent the laptop from overheating.

In some embodiments, the tray can include a raised element 464 on the top of the tray base member 420. The raised element 464 can be positioned at or near the back of the tray base member 420 so that the tray shelf 416 can rest against the raised element 464 when the tray shelf 416 is in the open configuration, as shown in the illustrated embodiment, or the raised element 464 can be positioned at or near the front of the tray base member 420 so that the tray shelf 416 can rest against the raised element 464 when the tray shelf 416 is in the closed configuration. In some embodiments, the tray base member 420 can include two or more raised elements 464, for example, positioned at or near both the back and front of the base member 420 so that the tray member 416 can rest against a raised member 464 in both the closed configuration and the open configuration. The at least one raised element 464 can be made from a compressible material (e.g., a closed cell foam). The raised element 464 can be a shock absorber to prevent the tray shelf 416 from striking the base member 420 when it is transitioned between the open and closed positions. In some embodiments, the raised element 464 can affect the position of the tray shelf 416 relative to the tray base member 420. For example, in the illustrated embodiment, a taller raised element 464 can raise the open-positioned tray shelf 416, and a shorter raised element 464 can allow the open-positioned tray shelf 416 to rest lower, closer to having the bottom surface 452 of the tray shelf 416 resting against the top of the tray base member 420. In some embodiments, the at least one raised element 464 can be interchangeable with other raised elements having different properties, such as different heights. For example, the raised element 464 can have a Velcro type hook and loop fastener element attached thereto that is configured to interface with a corresponding Velcro type hook and loop fastener element that is attached to the tray base member 420, although other fastening mechanisms can be used. Thus, in some embodiments, the user can adjust the angle of the tray shelf 416 relative to the tray base member 420 by changing the height of the attached raised element 464.

Various embodiments of equipment cases and trays are described herein. The various components, features, and other aspects of the embodiments described herein can be combined or interchanged to form additional embodiments not specifically described herein, which are contemplated as being a part of the present disclosure. In addition, while a number of variations have been shown and/or described in detail, other modifications, which are within the scope of this disclosure, will be readily apparent to those of skill in the art based upon this disclosure. Thus, it is intended that the scope of the disclosure should not be limited by the particular embodiments illustrated and/or described in detail.

What is claimed is:

1. An equipment case with integrated tray, comprising:
a bottom case member having an open top, a closed bottom surface, and sidewalls;
a top case member having an open bottom, a closed top surface, and sidewalls, wherein the top case member and bottom case member are configured to fit together to form an internal cavity;
a tray shelf having a support surface configured to support a laptop or other piece of equipment;
a tray base member coupled to the bottom case member, the tray base member defining a base axis that intersects the tray shelf and the bottom surface of the bottom case member, wherein the base axis is substantially stationary with respect to the bottom case member, and wherein the tray shelf is rotatably coupled to the tray base member and is configured to rotate about the base axis.

2. The equipment case of claim 1, wherein the tray shelf is rotatable between a closed position and at least one open position, and wherein the tray shelf fits within the internal cavity of the equipment case when in the closed position and extends outside an area of the internal cavity when in the at least one open position.

3. The equipment case of claim 1, wherein the tray shelf is rotatable about the base axis across 360 degrees.

4. The equipment case of claim 1, wherein the tray shelf has a hole through a generally central region of the tray shelf.

5. The equipment case of claim 4, wherein the top case member comprises at least one foam piece that is configured to fit through the hole in the tray shelf when the tray shelf is in a closed position and when the top case member is mounted onto the bottom case member.

6. The equipment case of claim 1, wherein the tray shelf is coupled to a shaft that is slidably received by the tray base member so that the shaft and tray shelf are movable axially along the base axis between a lowered position and at least one raised position.

7. The equipment case of claim 6, wherein the tray shelf is attached to the shaft at a pivot point that allows the tray shelf to pivot about a second axis that is substantially orthogonal to the base axis.

8. The equipment case of claim 6, wherein the shaft rotates with the tray shelf about the base axis.

9. The equipment case of claim 1, wherein the tray shelf is configured to pivot about a second axis that is substantially orthogonal to the base axis such that the tray shelf is movable between a flat position and at least one angled position.

10. The equipment case of claim 9, further comprising a tilt limiter configured to prevent rotation of the tray shelf past a predetermined range of rotation about the second axis.

11. The equipment case of claim 1, wherein the tray shelf is movable axially along the base axis between a lowered position and at least one raised position.

12. The equipment case of claim 1, wherein the tray shelf is movable axially along the base axis between a lowered position and at least one raised position, and wherein the tray shelf is configured to pivot about a second axis that is substantially orthogonal to the base axis such that the tray shelf is movable between a flat position and at least one angled position.

13. The equipment case of claim 1, wherein the tray shelf comprises at least one support projection extending generally away from the support surface to prevent the laptop or other piece of equipment from sliding off the support surface.

14. The equipment case of claim 1, wherein the base axis is substantially orthogonal to the bottom surface of the bottom case member.

15. The equipment case of claim 1, further comprising one or more foam pieces on an underside of the tray shelf and configured to rest against a piece of equipment in the internal cavity when the tray shelf is in a closed position.

16. The equipment case of claim 1, wherein the tray shelf is removably coupled to the bottom case member such that the tray shelf can be removed from the bottom case member.

17. The equipment case of claim 1, wherein the base axis intersects the top surface of the top case member when the top case member is mounted onto the bottom case member.

18. An equipment case with integrated tray, comprising:
a bottom case member having an open top, a closed bottom surface, and sidewalls;
a top case member having an open bottom, a closed top surface, and sidewalls, wherein the top case member and bottom case member are configured to fit together to form an internal cavity;
a tray shelf having a support surface configured to support a laptop or other piece of equipment;
a tray base member coupled to the bottom case member, the tray base member defining a base axis that intersects the tray shelf and the bottom surface of the bottom case member, wherein the base axis is substantially stationary with respect to the bottom case member, and wherein the tray shelf is movable between a plurality of positions disposed about the base axis.

19. The equipment case of claim 18, wherein the tray shelf fits within the internal cavity of the equipment case when in a closed position and extends outside an area of the internal cavity when in an open position.

20. The equipment case of claim 18, wherein the tray shelf has a hole through a generally central region of the tray shelf.

21. The equipment case of claim 20, wherein the top case member comprises at least one foam piece that is configured to fit through the hole in the tray shelf when the tray shelf is in a closed position and when the top case member is mounted onto the bottom case member.

22. The equipment case of claim 18, wherein the tray shelf is coupled to a shaft that is slidably received by the tray base member so that the shaft and tray shelf are movable axially along the base axis between a lowered position and at least one raised position.

23. The equipment case of claim 22, wherein the tray shelf is attached to the shaft at a pivot point that allows the tray shelf to pivot about a second axis that is substantially orthogonal to the base axis.

24. The equipment case of claim 18, wherein the tray shelf is configured to pivot about a second axis that is substantially orthogonal to the base axis such that the tray shelf is movable between a flat position and at least one angled position.

25. The equipment case of claim 24, further comprising a tilt limiter configured to prevent rotation of the tray shelf past a predetermined range of rotation about the second axis.

26. The equipment case of claim 18, wherein the tray shelf is movable axially along the base axis between a lowered position and at least one raised position.

27. The equipment case of claim 18, wherein the tray shelf is movable axially along the base axis between a lowered position and at least one raised position, and wherein the tray shelf is configured to pivot about a second axis that is substantially orthogonal to the base axis such that the tray shelf is movable between a flat position and at least one angled position.

28. The equipment case of claim 18, wherein the tray shelf comprises at least one support projection extending generally away from the support surface to prevent the laptop or other piece of equipment from sliding off the support surface.

29. The equipment case of claim 18, wherein the base axis is substantially orthogonal to the bottom surface of the bottom case member.

30. The equipment case of claim 18, wherein further comprising one or more foam pieces on an underside of the tray shelf and configured to rest against a piece of equipment in the internal cavity when the tray shelf is in a closed position.

31. The equipment case of claim 18, wherein the tray shelf is removably coupled to the bottom case member such that the tray base member and tray shelf can be removed from the bottom case member.

32. The equipment case of claim 18, wherein the base axis intersects the top surface of the top case member when the top case member is mounted onto the bottom case member.
